(19) United States
(12) Patent Application Publication
(10) Pub. No.: US 2025/0311495 A1
(43) Pub. Date: Oct. 2, 2025

(54) TRANSFER SUBSTRATE STRUCTURE, TRANSFER ASSEMBLY AND MICRODEVICE TRANSFER METHOD

(71) Applicant: Xiamen Extremely PQ Display Technology Co., Ltd., Xiamen (CN)

(72) Inventor: XIANGWEI XIE, Xiamen (CN)

(21) Appl. No.: 19/234,474

(22) Filed: Jun. 11, 2025

Related U.S. Application Data
(63) Continuation of application No. PCT/CN2022/139635, filed on Dec. 16, 2022.

(51) Int. Cl. H10H 29/03; H01L 25/075; H10H 29/855

(52) U.S. Cl. CPC H10H 29/03; H01L 25/0753; H10H 29/8552

(57) ABSTRACT

A transfer substrate structure, a transfer assembly and a microdevice transfer method are provided. The transfer substrate structure includes a substrate and a response layer. The substrate includes multiple light-transmitting regions spaced apart from each other and a non-light-transmitting region located between the multiple light-transmitting regions. The response layer is arranged on a side of the substrate and covering at least a part of the multiple light-transmitting regions. The response layer includes a material which is easy to decompose and release gas under irradiation of a laser with a preset wavelength. It can mitigate the effect of the transfer quality of microdevices due to the variations of laser spot.

### CROSS-REFERENCE TO RELATED APPLICATION

This application is a continuation of International Application No. PCT/CN2022/139635, filed on Dec. 16, 2022. The entire contents of the above-mentioned application are hereby incorporated by reference.

### TECHNICAL FIELD

The disclosure relates to the field of display technologies, and more particularly to a transfer substrate structure, a microdevice transfer assembly and a microdevice transfer method.

### BACKGROUND

In this situation, there is an urgent need to provide a transfer substrate structure to mitigate the effect of the transfer quality of microdevices due to the variations of laser spot.

### SUMMARY

In view of this, in order to overcome at least some defects in the related art, embodiments of the disclosure provide a transfer substrate structure, a transfer assembly and a microdevice transfer method, which can mitigate the effect of the transfer quality of microdevices due to the variations of laser spot.

In an aspect, an embodiment of the disclosure provides a transfer substrate structure, including a substrate and a response layer. The substrate includes multiple light-transmitting regions spaced apart from each other and a non-light-transmitting region located between the multiple light-transmitting regions. The response layer is arranged on a side of the substrate and covering at least a part of the multiple light-transmitting regions. The response layer includes a material which is easy to decompose and release gas under irradiation of a laser with a preset wavelength.

In an embodiment, the substrate includes a light-transmitting substrate and a light-blocking layer covering the light-transmitting substrate. The light-blocking layer is defined with multiple hollow patterns, and the multiple hollow patterns correspond to the plurality of light-transmitting regions in a one-to-one manner.

In an embodiment, the response layer covers a side of the light-blocking layer facing away from the light-transmitting substrate and fills the multiple hollow patterns.

In an embodiment, the response layer covers a side of the light-transmitting substrate facing away from the light-blocking layer.

In an embodiment, each of the multiple hollow patterns includes multiple hollow holes spaced apart from each other.

In an embodiment, each of the multiple hollow patterns is a centrally symmetric pattern.

In an embodiment, the light-blocking layer is a reflective material layer.

In an embodiment, the material of the response layer is any one or a combination selected from the group consisting of polyimide, triazene polymer, epoxy resin, polyurethane, fluorocarbon polymer, acrylic-based polymer, imide-based polymer and amide-based polymer.

In an embodiment, the material of the response layer includes one or at least two selected from the group consisting of rubber-based polymer, polyester, methylcarbamate-based polymer, polyether, silicone-based polymer, ethylene-vinyl acetate-based polymer, vinyl chloride-based polymer, cyanoacrylate-based polymer, cellulose-based polymer, phenol resin, polyolefin, styrene-based polymer, polyvinyl acetate, polyvinyl alcohol, polyvinyl acetal, polyvinylpyrrolidone, polyvinyl butyral, polybenzimidazole, melamine resin, urea resin, resorcinol-based polymer, polyvinyl ether adhesive, hydroxyphenyl triazine-based ultraviolet absorber, benzophenone-based ultraviolet absorber, benzotriazole-based ultraviolet absorber, benzoate-based ultraviolet absorber, benzoxazinone-based ultraviolet absorber, phenyl salicylate-based ultraviolet absorber, cyanoacrylate-based ultraviolet absorber, nickel complex ultraviolet absorber, hydroquinone-based ultraviolet absorber, salicylic acid-based ultraviolet absorber, malonate-based ultraviolet absorber, oxalic acid-based ultraviolet absorber, 2-dimethylamino-2-(4-methylbenzyl)-1-(4-morpholino-phenyl) butyl-1-one, [1-[9-ethyl-6-(2-methylbenzoylcarbazol-3-yl]ethylideneamino] acetate (also referred to as Ethanone, 1-[9-ethyl-6-(2-methylbenzoyl)-9H-carbazol-3-yl]-, 1-(O-acetyloxime), with a molecular formula of C₂₆H₂₄N₂O₃), [[1-oxo-1-(4-phenylsulfanylphenyl)octan-2-ylidene]amino] benzoate (also referred to as, 2-Octanedione, 1-[4-(phenylthio)phenyl]-, 2-(O-benzoyloxime), with a molecular formula of C₂₇H₂₇NO₃S), 2-benzyl-2-dimethylamino-1-(4-morpholinophenyl)butan-1-one, and 2-methyl-1-[4-(methylthio)phenyl]-2-morpholinopropan-1-one.

In an embodiment, the response layer includes multiple response parts spaced apart from each other.

In another aspect, an embodiment of the disclosure provides a transfer assembly, which includes the abovementioned transfer substrate structure and multiple microdevices. The multiple light-transmitting regions include multiple target light-transmitting regions covered by the response layer. The multiple microdevices are arranged in one-to-one correspondence with the multiple target light-transmitting regions and attached to the response layer.

In still another aspect, an embodiment of the disclosure provides a microdevice transfer method, which uses the abovementioned transfer substrate structure or the abovementioned transfer assembly.

### BENEFICIAL EFFECTS

The above embodiments of the disclosure have at least one or more beneficial effects as follows. By arranging the substrate with the light-transmitting regions and the non-light-transmitting region, the positions of microdevices corresponding to the light-transmitting regions can be adhered to the response layer. When a certain part of the response layer is irradiated by laser, only the material in the light-transmitting regions will decompose and release gas, so that the microdevices at the corresponding positions in the light-transmitting regions will fall off under the direct push or the bubbling push of the released gas. Even if the size of the laser spot is changed or the focusing position is shifted to irradiate the non-light-transmitting region and is blocked by the non-light-transmitting region, the region actually irradiated by the laser on the response layer is always equal to the size of the light-transmitting regions, that is, the region actually irradiated by the laser and decomposed by the response layer is not changed by the change of the laser spot. Therefore, the transfer quality can be prevented from being affected by the offset when the microdevice falls off.

### BRIEF DESCRIPTION OF DRAWINGS

Specific embodiments of the disclosure will be described in detail with reference to the accompanying drawings.

FIG. 1 illustrates a schematic structural view of a transfer substrate structure according to an embodiment of the disclosure.

FIG. 2 illustrates a schematic structural view of a substrate of the transfer substrate structure illustrated in FIG. 1 according to an embodiment of the disclosure.

FIG. 3 illustrates a schematic sectional view of the substrate along a line B-B illustrated in FIG. 2.

FIG. 4 illustrates a schematic view of a light transmission principle of the substrate illustrated in FIG. 3.

FIG. 5 illustrates a schematic view of a transfer substrate structure along a line A-A illustrated in FIG. 1 using the substrate illustrated in FIG. 2 according to an embodiment of the disclosure.

FIG. 6 illustrates a schematic view of a transfer substrate structure along a line A-A illustrated in FIG. 1 using the substrate illustrated in FIG. 2 according to another embodiment of the disclosure.

FIG. 7 illustrates a schematic structural view of a substrate of the transfer substrate structure illustrated in FIG. 1 according to another embodiment of the disclosure.

FIG. 8 illustrates a schematic sectional view of the substrate along a line C-C illustrated in FIG. 7.

FIG. 9 illustrates a schematic sectional view of a transfer substrate structure along a line A-A illustrated in FIG. 1 using the substrate illustrated in FIG. 7 according to an embodiment of the disclosure.

FIG. 10 illustrates a schematic sectional view of a transfer substrate structure along a line A-A illustrated in FIG. 1 according to another embodiment of the disclosure.

FIG. 11 illustrates a schematic structural view of a transfer substrate structure according to another embodiment of the disclosure.

FIG. 12 illustrates a schematic structural view of a transfer substrate structure according to still another embodiment of the disclosure.

FIG. 13 illustrates a schematic view of a manufacturing process of the transfer substrate structure according to an embodiment of the disclosure.

FIG. 14 illustrates a schematic structural view of a transfer assembly according to an embodiment of the disclosure.

FIG. 15 illustrates a schematic sectional view of a transfer assembly along a line D-D illustrated in FIG. 14 according to an embodiment of the disclosure.

FIG. 16 illustrates a schematic sectional view of a transfer assembly along the line D-D illustrated in FIG. 14 according to another embodiment of the disclosure.

FIG. 17 illustrates a schematic sectional view of a transfer assembly along the line D-D illustrated in FIG. 14 according to still another embodiment of the disclosure.

FIG. 18 illustrates a schematic sectional view of a transfer assembly according to another embodiment of the disclosure.

FIG. 19 illustrates a schematic flowchart of a microdevice transfer method according to an embodiment of the disclosure.

### DESCRIPTION OF REFERENCE SIGNS

100: transfer substrate structure; 10: substrate; 11: light-transmitting region; 12: non-light-transmitting region; 13: light-transmitting substrate; 14: light-blocking layer; 141: hollow pattern; 1411: hollow hole; 20: response layer; 21: response part; 211: intermediate response piece; 212: peripheral response piece; 200: microdevice; 300: transfer assembly.

### DETAILED DESCRIPTION OF EMBODIMENTS

In order to make the abovementioned purposes, features and advantages of the disclosure be more readily understood, embodiments of the disclosure will be described in detail with reference to the accompanying drawings.

In order for those skilled in the art to better understand the technical solutions of the disclosure, technical solutions of the embodiments of the disclosure will be clearly and completely described below in conjunction with the drawings in the embodiments of the disclosure. Apparently, the described embodiments are only a part of the embodiments of the disclosure, not all of the embodiments. Based on the embodiments in the disclosure, all other embodiments obtained by those skilled in the art without creative work should fall within the scope of protection of the disclosure.

It should be noted that terms “first” and “second” in the description and claims of the disclosure and the accompanying drawings are used to distinguish similar objects, and are not necessarily used to describe a specific order or sequence. It should be understood that the terms so used are interchangeable under appropriate circumstances, so that the embodiments of the disclosure described herein can be implemented in other orders than those illustrated or described herein. Furthermore, terms “including” and “having” and any variations thereof are intended to cover non-exclusive inclusion, for example, processes, methods, systems, products or an equipment that includes a series of steps or units is not necessarily limited to those explicitly listed, but may include other steps or units not explicitly listed or inherent to these processes, methods, products or equipment.

It should also be noted that the division of multiple embodiments in the disclosure is only for the convenience of description, and should not constitute a special limitation. The features in various embodiments can be combined and quoted from each other without contradiction.

In the related art, the principle of laser-assisted transfer technology is that one or more layers of response materials are attached to a transparent substrate to adhere Micro light-emitting diode (LED) chips and other microdevices. When the chips need to be released to a target substrate, the response lay material at the position where the chips need to be transferred is irradiated by a laser. After the response layer material is irradiated by the laser, for example, gas is directly decomposed, directly pushed by the gas or pushed by the formed bubbles, so that the microdevices are detached from the transparent substrate to fall onto the target substrate to complete the transfer. A size of a decomposition region of the response layer is controlled by a size of a laser spot. If the size of the laser spot is changed, for example, the size of the laser spot is changed due to the deviation of the substrate from a focusing position or the change of the focusing position of the laser, the decomposition region of the response layer will be affected, so that the size of gasification or bubbling is changed, thereby affecting an initial state of the microdevice, for example, an initial speed is changed, and a flying state after the microdevice is detached is changed. In this way, the position where the chips finally fall on the target substrate is shifted, resulting in deterioration of transfer accuracy. In addition, if the decomposition region of the response layer is too large, it may affect the adjacent chips, and if the spot position is shifted at the same time, it may further lead to the shift and affect an angle of the microdevice. Therefore, an embodiment of the disclosure provides a transfer substrate structure to mitigate the effect the transfer quality of the microdevices due to the variations of laser spot.

### First Embodiment

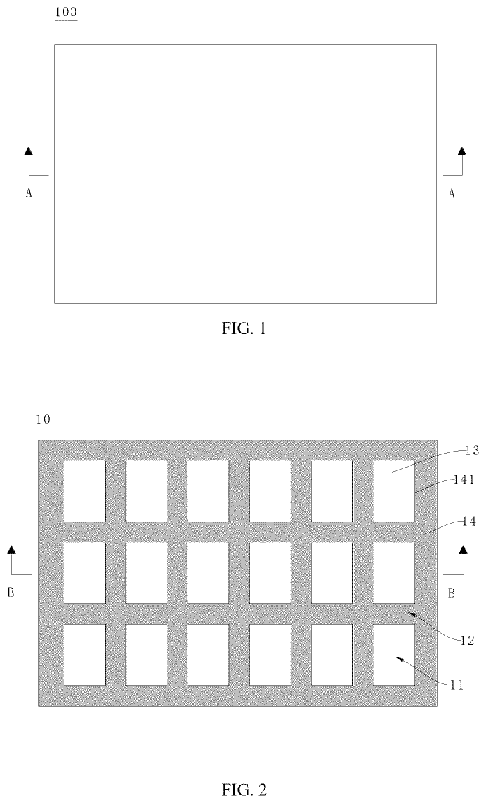

A transfer substrate structure 100 provided by the first embodiment of the disclosure can be used to transfer Micro LED and devices with similar laser transfer requirements. Referring to FIG. 1 to FIG. 5, the transfer substrate structure 100 includes a substrate 10 and a response layer 20. The substrate 10 includes multiple light-transmitting regions 11 spaced apart from each other and a non-light-transmitting region 12 located between the multiple light-transmitting regions 11. The response layer 20 is disposed on a side of the substrate 10, and covers at least a part of the multiple light-transmitting regions 11. The response layer 20 includes a material that is easily decomposed and generates gas under irradiation of a laser with a preset wavelength.

Specifically, referring to the substrate 10 illustrated in FIG. 2, the 18 small rectangular regions in three rows and six columns illustrated in FIG. 2 are the multiple light-transmitting regions 11, and the gray filled region between the light-transmitting regions 11 is non-light-transmitting region 12. It can be understood that in this embodiment, the light-transmitting regions 11 refer to the regions where the laser with a specific wavelength, such as ultraviolet laser or deep ultraviolet laser, can be transmitted through the substrate 10 and reach the response layer 20. The non-light-transmitting region 12 refers to a region where the laser with the specific wavelength used in transfer cannot reach the response layer 20 by penetrating through the substrate 10. The material of the response layer 20 can be, for example, polyimide (PI), triazene polymer (TP), epoxy resin, polyurethane, fluorocarbon polymer, acrylic-based polymer, imide-based polymer and amide-based polymer, which are easily decomposed by laser irradiation and can release gas, and can be any one or a combination of multiple materials.

Specifically, the response layer 20 may include other viscous materials besides the materials that are easily decomposed and release gas under the irradiation of the laser with the preset wavelength. In some embodiments, the response layer 20 includes, for example, one or at least two selected from the group consisting of rubber-based polymers (such as natural rubber, chloroprene rubber, styrene-butadiene rubber, nitrile rubber, etc.), polyester, urethane-based methylcarbamate-based polymer (i.e., polyurethane), polyether, silicone-based polymer, ethylene-vinyl acetate-based polymer, vinyl chloride-based polymer, cyanoacrylate-based polymer, cellulose-based polymer, phenol resin, polyolefin, styrene-based polymer, polyvinyl acetate, polyvinyl alcohol, polyvinyl acetal, polyvinylpyrrolidone, polyvinyl butyral, polybenzimidazole, melamine resin, urea resin, resorcinol-based polymer, polyvinyl ether adhesive.

In some embodiments, the response layer 20 may further include a laser absorption material, so that the response layer 20 can better absorb the laser to decompose into gaseous volatile products.

For example, the laser absorption material can include an ultraviolet absorber to better absorb ultraviolet laser. The ultraviolet absorber can be, for example, hydroxyphenyl triazine-based ultraviolet absorber, benzophenone-based ultraviolet absorber, benzotriazole-based ultraviolet absorber, benzoate-based ultraviolet absorber, benzoxazinone-based ultraviolet absorber, phenyl salicylate-based ultraviolet absorber, cyanoacrylate-based ultraviolet absorber, nickel complex ultraviolet absorber, hydroquinone-based ultraviolet absorber, salicylic acid-based ultraviolet absorber, malonate-based ultraviolet absorber, oxalic acid-based ultraviolet absorber, etc., which can be any one or a combination of at least two.

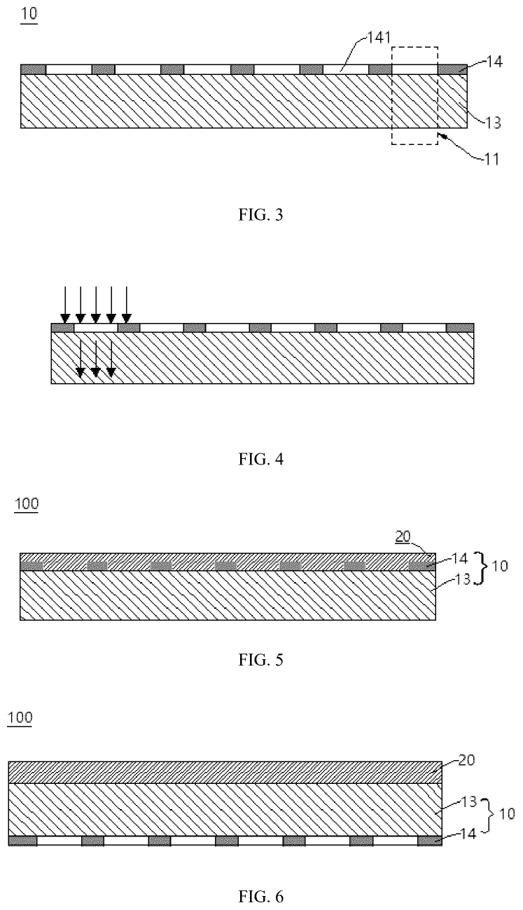

The laser absorption material includes, for example, a photopolymerization initiator, which be, for example, 2-dimethylamino-2-(4-methylbenzyl)-1-(4-morpholino-phenyl)butyl-1-one, [1-[9-ethyl-6-(2-methylbenzoyl)carbazol-3-yl]ethylideneamino] acetate, [[1-oxo-1-(4-phenylsulfanylphenyl)octan-2-ylidene]amino] benzoate, 2-benzyl-2-dimethylamino-1-(4-morpholinophenyl)butan-1-one, and 2-methyl-1-[4-(methylthio)phenyl]-2-morpholinopropan-1-one, etc., which can be any one or a combination of at least two. Referring to FIG. 3, in an embodiment, the substrate 10 includes, for example, a light-transmitting substrate 13 and a light-blocking layer 14 covering the light-transmitting substrate 13. The light-blocking layer 14 has multiple hollow patterns 141, and the multiple hollow patterns 141 correspond to the plurality of light-transmitting regions 11 in a one-to-one manner. For example, the light-transmitting substrate 13 can transmit the laser with the specific wavelength used in microdevice transfer, such as a sapphire substrate, a glass substrate, a quartz substrate, etc. The material of the light-blocking layer 14 is a material that can block the transmission of the laser with the specific wavelength used in the transfer, for example, it can be a reflective material layer, specifically, it can be a metal thin film such as chromium (Cr), titanium (Ti) or molybdenum (Mo) that is well irradiated and can reflect the laser, or it can be a distributed Bragg reflection (DBR) layer. The laser may pass through the substrate 10 from the hollow patterns 141.

The principle that this embodiment can mitigate the effect of transfer quality due to the size change of laser spot is as follows. Referring to FIG. 4, arrows are the irradiation direction of laser beam, and multiple parallel arrows represent the width of laser beam. In FIG. 4, the laser beam is incident from a side of the light-blocking layer 14 facing away from the light-transmitting substrate 13, but it can also be incident from a side of the light-transmitting substrate 13 facing away from the light-blocking layer 14 (not shown in FIG. 4). The laser beam irradiated on the light-blocking layer 14 is wide, but only the laser beam irradiated on the hollow patterns 141 (i.e., the light-transmitting regions 11) can pass through the substrate 10. The laser beam irradiated to the substrate 10 without the hollow patterns 141 (i.e., the non-light-transmitting region 12) cannot pass through the substrate 10, that is, when the laser beam passes through one side of the substrate 10 to the other side, regardless of the size of the incident laser spot, the maximum spot size that finally passes through the substrate 10 can only be equal to the size of the light-transmitting regions 11. Therefore, after the substrate 10 is covered with the response layer 20, the microdevices can be adhered to the light-transmitting regions 11 covered with the response layer 20, and the size of the decomposition region of the response layer 20 will not change with the laser spot size during laser irradiation, so that the detachment state of the microdevices is not affected by the laser spot change, and the transfer quality is guaranteed. It should be noted that in this embodiment, the response layer 20 is not limited to covering all the light-transmitting regions 11 on the substrate 10, and only a part of the light-transmitting regions 11 need to be covered by the response layer 20, so that the transfer substrate structure 100 can correspondingly adhere some microdevices to some light-transmitting regions 11. For example, in some embodiments, after the transfer of some microdevices has been completed, the response layer 20 corresponding to the transferred microdevices has been decomposed, so its corresponding light-transmitting regions 11 are no longer covered by the response layer 20.

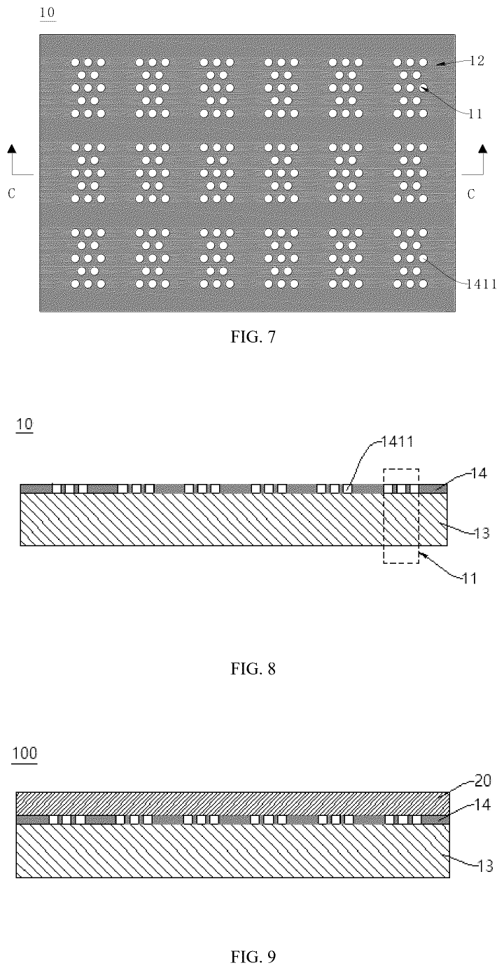

Referring to FIG. 5, the response layer 20 covers the side of the light-blocking layer 14 facing away from the light-transmitting substrate 13 and is filled with multiple hollow patterns 141. That is, the light-blocking layer 14 and the response layer 20 are arranged on the same side of the light-transmitting substrate 13. However, in other embodiments, referring to FIG. 6, the response layer 20 can also be covered on the side of the light-transmitting substrate 13 facing away from the light-blocking layer 14, and this embodiment is not limited.

Referring to FIG. 7 to FIG. 9, in an embodiment, each of the multiple hollow patterns 141 includes multiple hollow holes 1411 spaced apart from each other. One light-transmitting region 11 can correspond to an adhesion position of one microdevice. In this situation, a size of a circumscribed rectangle of the hollow pattern 141 corresponding to each light-transmitting region 11 is similar to that of the transferred microdevice, and generally slightly smaller than that of the microdevice. A total area of the multiple hollow holes 1411 in each hollow pattern 141 determines the size of the irradiated decomposition region of the response layer 20, so the transfer state of the microdevices can be controlled by designing the size, gap and arrangement of the multiple hollow holes 1411.

In an embodiment, each hollow pattern 141 of the multiple hollow patterns 141 is a centrally symmetric pattern, which can be, for example, a square, a diamond, a hexagon, a circle, an ellipse and the like. The symmetrical hollow pattern 141 makes the region of the response layer 20 irradiated and decomposed symmetrical. Therefore, a uniform thrust can be released on the microdevices, allowing the microdevices to fall vertically after being separated from the transfer substrate structure 100, and further improving the transfer accuracy.

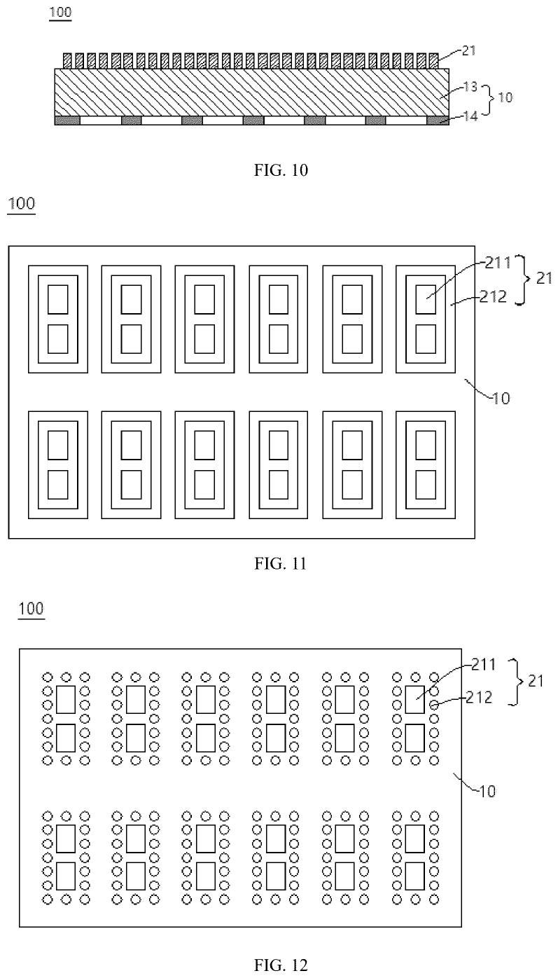

Referring to FIG. 10, in an embodiment, the response layer 20 includes multiple response parts 21 spaced apart from each other. Setting the response layer 20 as the multiple independent response parts 21 can make the response layer 20 in the laser irradiated region decompose faster and more evenly during transfer, and can also reduce the influence on microdevices in adjacent positions. It should be noted that FIG. 10 only shows an example in which the response layer 20 and the light-blocking layer 14 are arranged on opposite sides of the light-transmitting substrate 13. As described in the above embodiment, when the response layer 20 includes multiple response parts 21, the response layer 20 may be arranged on the same side of the light-blocking layer 14.

Materials of the multiple response parts 21 may be the same or different, for example, some response parts 21 include a laser absorption material, and other response parts 21 do not include the laser absorption material. For example, the laser absorption material in the partial response parts 21 is an ultraviolet absorber material and the laser absorption material in the partial response parts 21 is a photopolymerization initiator material. For example, some response parts 21 include an acrylic polymer and an oxalic acid-based ultraviolet absorber. Alternatively, other response parts 21 includes polyimide and ethanone. Alternatively, still other response parts 21 include epoxy resin, salicylic acid ultraviolet absorber and 2-benzyl-2-dimethylamino-1-(4-morpholinophenyl)-butan-1-one. The above examples illustrate some combinations of the materials of the response parts 21, and there are more combinations, which are not illustrated in this embodiment.

In some embodiments, the response layer 20 may have a single-layer material structure or a multi-layer material structure. When the response layer 20 includes multiple response parts 21, the response parts 21 may also have a single-layer material structure or a multi-layer material structure. For example, one side of the response part 21 close to the substrate 10 is provided with an inner layer material that can be decomposed by laser to release gas, and the other side of the inner layer material facing away from the substrate 10 is provided with an outer layer material, which can be made of viscose materials such as silica gel, so that the microdevice can be adhered through the outer layer material, and the microdevice can be separated from the substrate 10 through the laser decomposition of the inner layer material to release gas. The multiple response parts 21 are spaced apart from each other, and only the response part 21 corresponding to the light-transmitting region 11 irradiated by the laser is released, and the response part 21 whose periphery is blocked by the light-blocking layer 14 but not irradiated by the laser is released. For example, the inner layer material of one of the response parts 21 may be a triazene polymer, and the outer layer material may be natural rubber.

In some embodiments, each response part 21 may include an intermediate response piece 211 and a peripheral response piece 212 surrounding the intermediate response piece 211. There may be one or more intermediate response pieces 211 and one or more peripheral response pieces 212. Materials of the intermediate response piece 211 and the peripheral response piece 212 may be the same or different. For example, referring to FIG. 11, the peripheral response piece 212 may have an annular structure, forming a cavity around the intermediate response pieces 211. For example, the material of the intermediate response piece 211 can be easily decomposed by laser to release gas. For example, the material of the intermediate response piece 211 can be a combination of epoxy resin, hydroquinone ultraviolet absorber and ethanone, and the peripheral response piece 212 can be a viscous material such as silica gel. When transferring the microdevice, the microdevice can be adhered to the peripheral response piece 212 and enclosed with the peripheral response piece 212 and the substrate 10 to form a closed chamber. The intermediate response piece 212 can be irradiated by laser to decompose the intermediate response piece 211 to release gas to push the microdevice to separate from the peripheral response piece 212 and be transferred. In this embodiment, when the material of the intermediate response piece 211 is a material that is easily decomposed by laser to release gas, and the peripheral response piece 212 is the viscous material such as silica gel, a height at which the intermediate response piece 211 protrudes from the substrate 10 may be smaller than a height at which the peripheral response piece 212 protrudes from the substrate 10. In some embodiments, when the peripheral response piece 212 is selected as a glue material whose viscosity is not affected by laser, an orthographic projection of the peripheral response piece 212 on the substrate 10 can be located in the light-transmitting region 11 or the non-light-transmitting region 12. When the peripheral response piece 212 is selected as a glue material with reduced viscosity after laser irradiation, the orthogonal projection of the peripheral response piece 212 on the substrate 10 is located in the non-light-transmitting region 12, so that it is not affected by the laser spot size, and the microdevice is pushed away from the substrate 10 mainly by the thrust of the gas released by the decomposition of the intermediate response piece 211.

In some embodiments, referring to FIG. 12, each response part 21 includes two intermediate response pieces 211 and multiple peripheral response pieces 212 surrounding the intermediate response piece 211. The intermediate response piece 211 has a first adhesion area, and the peripheral response piece 212 has a second adhesion area, and the first adhesion area is larger than the second adhesion area. In this embodiment, the first adhesion area refers to the area of the surface of the intermediate response piece 211 facing away from the substrate 10, that is, the area where the intermediate response piece 211 can contact with the microdevice, for example, the first adhesion area of each response part 21 is the rectangular area of one intermediate response piece 211 in FIG. 12. The second adhesion area refers to the area of the surface of the peripheral response piece 212 facing away from the substrate 10, that is, the area where the peripheral response piece 212 can contact with the microdevice. For example, the second adhesion area in FIG. 12 is the circular area of each peripheral response piece 212. The smaller size setting of the peripheral response piece 212 can further reduce the impact on adjacent microdevices during transfer.

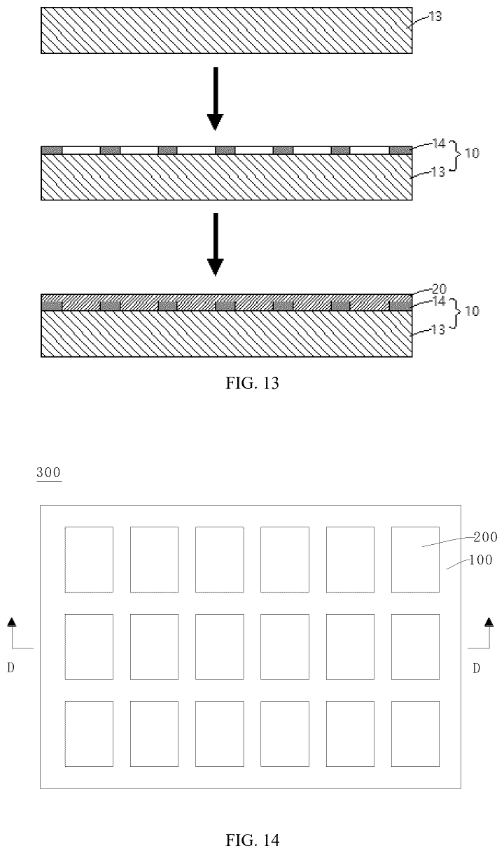

FIG. 13 illustrates a schematic view of a manufacturing process of the transfer substrate structure 100 according to this embodiment. First, the light-transmitting substrate 13 is provided, and then the light-blocking layer 14 with the hollow patterns 141 is formed on the light-transmitting substrate 13 to obtain the substrate 10. Finally, the material of the response layer 20 is coated on one side of the substrate 10, and the transfer substrate structure 100 is obtained after the material of the response layer 20 is cured.

### Second Embodiment

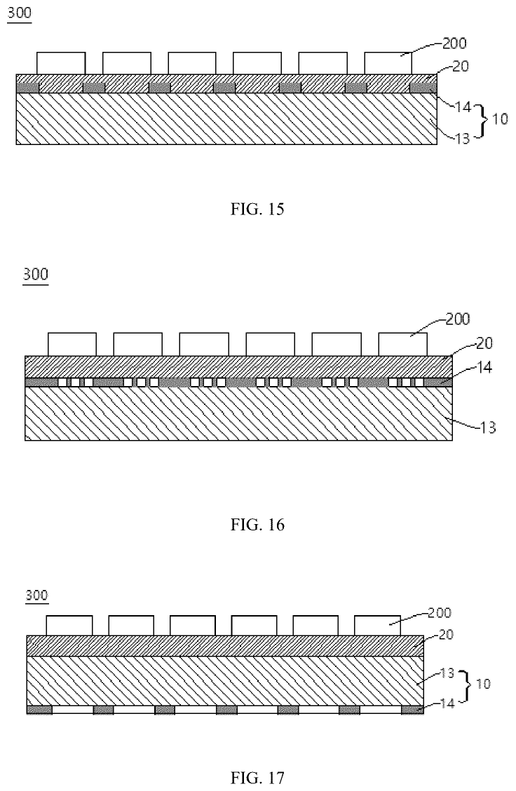

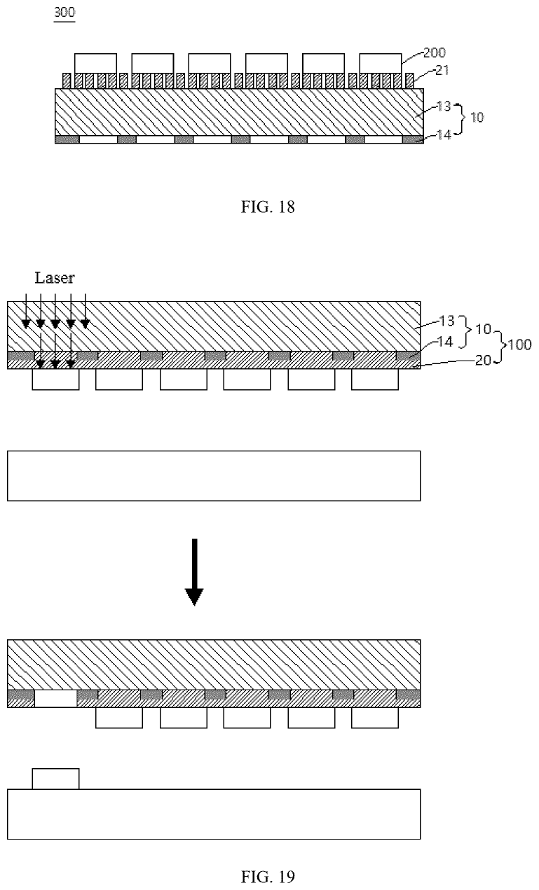

The second embodiment of the disclosure provides a transfer assembly 300. Referring to FIG. 14, the transfer assembly 300 includes any transfer substrate structure 100 provided in the first embodiment, and further includes multiple microdevices 200. In this embodiment, for convenience of description, the multiple light-transmitting regions 11 covered by the response layer 20 are called target light-transmitting regions 11, and the multiple light-transmitting regions 11 includes multiple target light-transmitting regions 11. The multiple microdevices 200 are arranged in one-to-one correspondence with the multiple target light-transmitting regions 11 and attached to the response layer 20. FIG. 15 is a schematic sectional view of the transfer assembly 300 along a line D-D corresponding to the transfer substrate structure 100 shown in FIG. 5. FIG. 16 is a schematic sectional view of the transfer assembly 300 along the line D-D corresponding to the transfer substrate structure 100 shown in FIG. 9. FIG. 17 is a schematic sectional view of the transfer assembly 300 along the line D-D corresponding to the transfer substrate structure 100 shown in FIG. 6. FIG. 18 is a schematic sectional view of the transfer assembly 300 along the line D-D corresponding to the transfer substrate structure 100 shown in FIG. 10. In an embodiment, among the multiple response parts 21 of the response layer 20, each response part 21 is connected with only one microdevice 200 at most. In FIG. 15 to FIG. 18, each light-transmitting region 11 is covered by the response layer 20, and each light-transmitting region 11 can be called the target light-transmitting region 11. One microdevice 200 corresponds to one target light-transmitting region 11 and adheres to the response layer 20. For a detailed description of the transfer substrate structure 100, please refer to the description in the first embodiment of the disclosure. The microdevice 200 can be a Miro LED chip or other devices with similar transfer requirements. This embodiment is not limited.

### Third Embodiment

An embodiment of the disclosure further provides a microdevice transfer method, which uses any transfer substrate structure 100 provided in the first embodiment or any transfer assembly 300 provided in the second embodiment. Referring to FIG. 19, the transfer substrate structure 100 or the transfer assembly 300 with the microdevices attached is provided, and the corresponding position of the microdevices to be transferred is irradiated by laser. Even if the laser spot is larger than the size of the light-transmitting region 11, the size of the irradiated region of the response layer 20 will not be affected, so only the material of the response layer 20 corresponding to the light-transmitting region 11 is decomposed, the microdevices are directly pushed by the gas released by decomposition or bubbles formed by the gas to separate from the transfer substrate structure 100 and fall onto a target substrate, and finally the transfer is completed. This transfer process is not affected by the change of the size of the laser spot, which can ensure the transfer quality and accuracy of the microdevices.

The above is only illustrated embodiments of the disclosure, and are not intended to limit this disclosure in any form. Although the disclosure has been disclosed in the illustrated embodiments as described above, it is not intended to limit the disclosure. Any person skilled in the art can make some changes or modify the disclosure into an equivalent embodiment by using the technical content disclosed above within the scope of the technical solutions of the disclosure. However, whatever is done to the above embodiments according to the technical essence of the disclosure without departing from the technical solutions of this disclosure.

What is claimed is:

1. A transfer substrate structure, comprising:
a substrate, comprising a plurality of light-transmitting regions spaced apart from each other and a non-light-transmitting region located between the plurality of light-transmitting regions; and
a response layer, arranged on a side of the substrate and covering at least a part of the plurality of light-transmitting regions; wherein the response layer comprises a material and the material is easy to be decomposed and release gas under irradiation of a laser with a preset wavelength.

2. The transfer substrate structure as claimed in claim 1, wherein the substrate comprises:
a light-transmitting substrate; and
a light-blocking layer, covering the light-transmitting substrate; wherein the light-blocking layer is defined with a plurality of hollow patterns, and the plurality of hollow patterns correspond to the plurality of light-transmitting regions in a one-to-one manner.

3. The transfer substrate structure as claimed in claim 2, wherein the response layer covers a side of the light-blocking layer facing away from the light-transmitting substrate and fills the plurality of hollow patterns.

4. The transfer substrate structure as claimed in claim 2, wherein the response layer covers a side of the light-transmitting substrate facing away from the light-blocking layer.

5. The transfer substrate structure as claimed in claim 2, wherein each of the plurality of hollow patterns is defined with a plurality of hollow holes spaced apart from each other.

6. The transfer substrate structure as claimed in claim 2, wherein each of the plurality of hollow patterns is a centrally symmetric pattern.

7. The transfer substrate structure as claimed in claim 2, wherein the light-blocking layer is a reflective material layer.

8. The transfer substrate structure as claimed in claim 1, wherein the material of the response layer is any one or a combination selected from the group consisting of polyimide, triazene polymer, epoxy resin, polyurethane, fluorocarbon polymer, acrylic-based polymer, imide-based polymer and amide-based polymer.

9. The transfer substrate structure as claimed in claim 1, wherein the material of the response layer comprises any one or a combination of at least two selected from the group consisting of rubber-based polymer, polyester, methylcarbamate-based polymer, polyether, silicone-based polymer, ethylene-vinyl acetate-based polymer, vinyl chloride-based polymer, cyanoacrylate-based polymer, cellulose-based polymer, phenol resin, polyolefin, styrene-based polymer, polyvinyl acetate, polyvinyl alcohol, polyvinyl acetal, polyvinylpyrrolidone, polyvinyl butyral, polybenzimidazole, melamine resin, urea resin, resorcinol-based polymer, polyvinyl ether adhesive, hydroxyphenyl triazine-based ultraviolet absorber, benzophenone-based ultraviolet absorber, benzotriazole-based ultraviolet absorber, benzoate-based ultraviolet absorber, benzoxazinone-based ultraviolet absorber, phenyl salicylate-based ultraviolet absorber, cyanoacrylate-based ultraviolet absorber, nickel complex ultraviolet absorber, hydroquinone-based ultraviolet absorber, salicylic acid-based ultraviolet absorber, malonate-based ultraviolet absorber, oxalic acid-based ultraviolet absorber, 2-dimethylamino-2-(4-methylbenzyl)-1-(4-morpholino-phenyl)butyl-1-one, [1-[9-ethyl-6-(2-methylbenzoyl)carbazol-3-yl]ethylideneamino] acetate, [[1-oxo-1-(4-phenylsulfanylphenyl)octan-2-ylidene]amino] benzoate, 2-benzyl-2-dimethylamino-1-(4-morpholinophenyl)butan-1-one, and 2-methyl-1-[4-(methylthio)phenyl]-2-morpholinopropan-1-one.

10. The transfer substrate structure as claimed in claim 1, wherein the response layer comprises a plurality of response parts spaced apart from each other.

11. The transfer substrate structure as claimed in claim 10, wherein materials of the plurality of response parts are same or different.

12. The transfer substrate structure as claimed in claim 10, wherein the response layer has a single-layer material structure or a multi-layer material structure.

13. The transfer substrate structure as claimed in claim 10, wherein each of the plurality of response parts comprises an intermediate response piece and a peripheral response piece surrounding the intermediate response piece.

14. The transfer substrate structure as claimed in claim 13, wherein the peripheral response piece is defined as an annular structure surrounding the intermediate response piece.

15. The transfer substrate structure as claimed in claim 14, wherein a height of the intermediate response piece protruding from the substrate is smaller than a height of the peripheral response piece protruding from the substrate.

16. The transfer substrate structure as claimed in claim 10, wherein each of the plurality of response parts comprises two intermediate response piece and a plurality of peripheral response pieces surrounding the two intermediate response pieces.

17. The transfer substrate structure as claimed in claim 16, wherein a first adhesion area of each of the intermediate response pieces is greater than a second adhesion area of each of the plurality of peripheral response pieces.

18. A transfer assembly comprising:
the transfer substrate structure as claimed in claim 1, wherein the plurality of light-transmitting regions comprise a plurality of target light-transmitting regions covered by the response layer; and
a plurality of microdevices, arranged in one-to-one correspondence with the plurality of target light-transmitting regions and attached to the response layer.

19. A microdevice transfer method, using the transfer substrate structure as claimed in claim 1.

20. A microdevice transfer method, using the transfer assembly as claimed in claim 18.
